(19) United States
(12) Patent Application Publication
(10) Pub. No.: US 2025/0285869 A1
(43) Pub. Date: Sep. 11, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Chao-Hsuan CHEN, Hsinchu (TW); I-Wei YANG, Yilan (TW); Wen-Shuo HSIEH, Taipei (TW); Shu-Yuan KU, Hsinchu (TW); Ryan Chia-Jen CHEN, Hsinchu (TW)

(21) Appl. No.: 18/598,197

(22) Filed: Mar. 7, 2024

(51) Int. Cl. H01L 21/28; H01L 29/06; H01L 29/423; H01L 29/66; H01L 29/775

(52) U.S. Cl. CPC H01L 21/28123; H10D 30/014; H10D 30/43; H10D 30/6735; H10D 62/121; H10D 64/017

(57) ABSTRACT

Embodiments of the present disclosure provide a method for forming a semiconductor device structure. The method includes forming a fin structure over a substrate, forming an insulating material adjacent the fin structure, depositing a gate dielectric layer over the fin structure, depositing a gate electrode layer on the gate dielectric layer, and forming an opening through the gate electrode layer and the gate dielectric layer into the insulating material by a cyclic process. The cyclic process includes performing a first number of cycles, each cycle of the first number of cycles includes a first main etch process having a first plasma bias voltage, performing a second number of cycles, and each cycle of the second number of cycles includes a second main etch process having a second plasma bias voltage substantially greater than the first plasma bias voltage. The method further includes filling the opening with a dielectric material.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device structure, in accordance with some embodiments.

FIGS. 7A-11A are cross-sectional side views of various stages of manufacturing the semiconductor device structure taken along line A-A of FIG. 6, in accordance with some embodiments.

FIGS. 7B-11B are cross-sectional side views of various stages of manufacturing the semiconductor device structure taken along line B-B of FIG. 6, in accordance with some embodiments.

FIGS. 7C-11C are cross-sectional side views of various stages of manufacturing the semiconductor device structure taken along line C-C of FIG. 6, in accordance with some embodiments.

FIGS. 12A-12D are cross-sectional side views of various stages of manufacturing the semiconductor device structure taken along line B-B of FIG. 6, in accordance with some embodiments.

FIGS. 13A-13C are various views of one of various stages of manufacturing the semiconductor device structure, in accordance with some embodiments.

FIG. 14 is a cross-sectional side view of one of various stages of manufacturing the semiconductor device structure, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

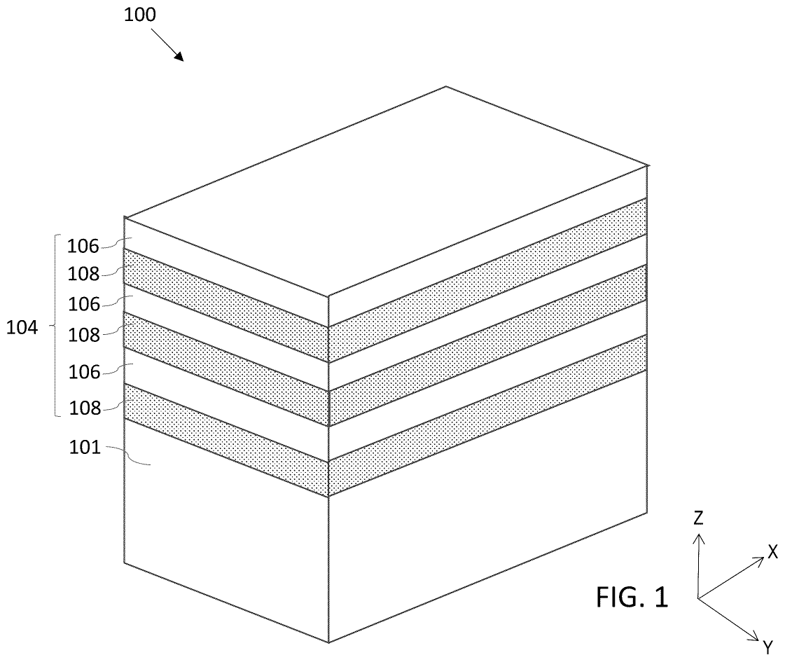

FIGS. 1-13C show exemplary processes for manufacturing a semiconductor device structure 100 according to embodiments of the present disclosure. It is understood that additional operations can be provided before, during, and after processes shown by FIGS. 1-13C, and some of the operations described below can be replaced or eliminated, for additional embodiments of the method. The order of the operations/processes is not limiting and may be interchangeable.

FIGS. 1-6 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

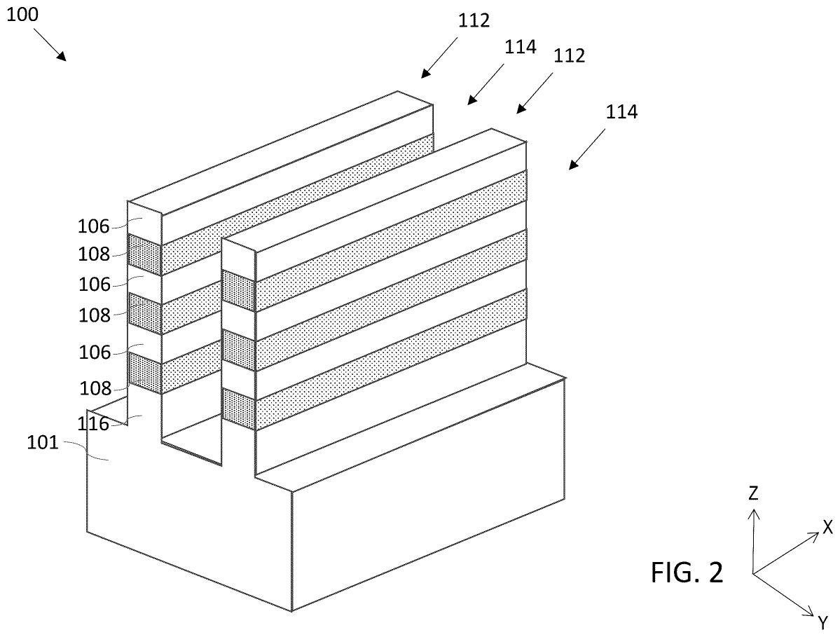

In FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

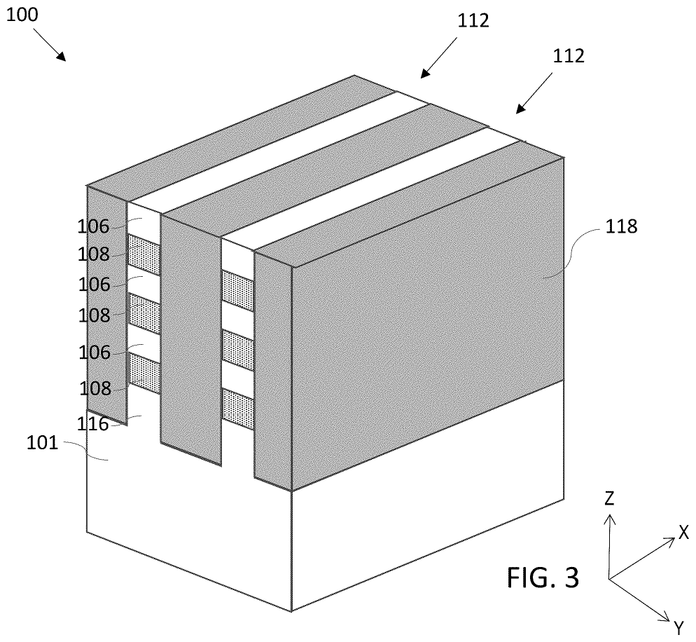

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

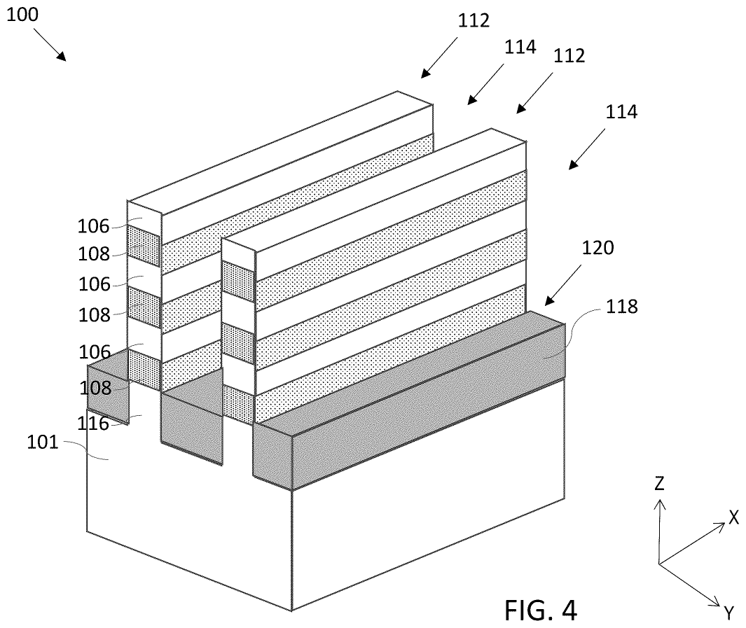

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the well portion 116 formed from the substrate 101.

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. In some embodiments, the gate spacers 138 are also formed on sidewalls of the exposed portions of the fin structures 112. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device structure 100.

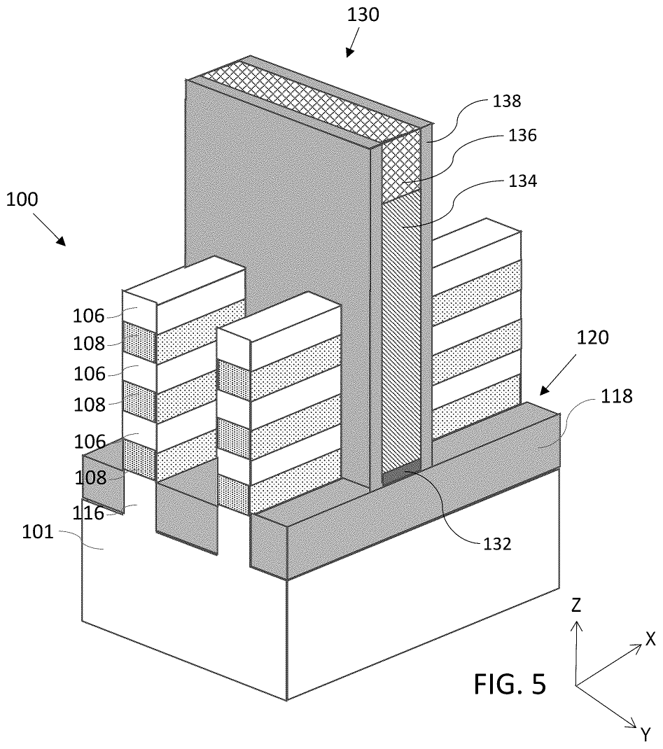

In FIG. 6, the portions of the fin structures 112 not covered by the sacrificial gate structure 130 and the gate spacers 138 are recessed to a level above, at, or below the top surfaces of the isolation regions 120. The recess of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant.

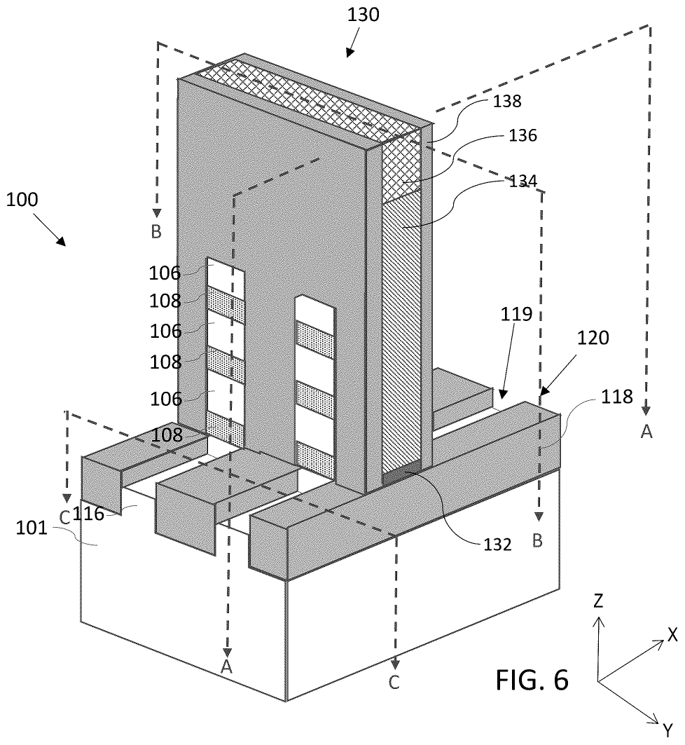

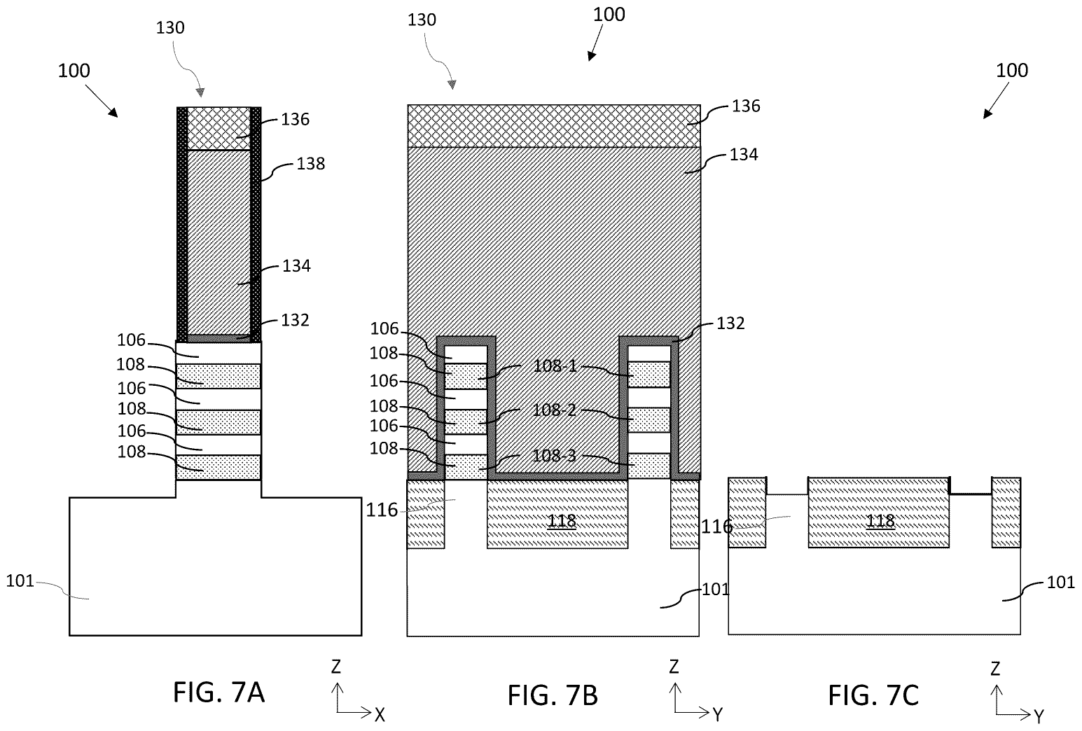

FIGS. 7A, 7B, and 7C are cross-sectional side views of the semiconductor device structure 100 taken along line A-A, line B-B, and line C-C of FIG. 6, respectively.

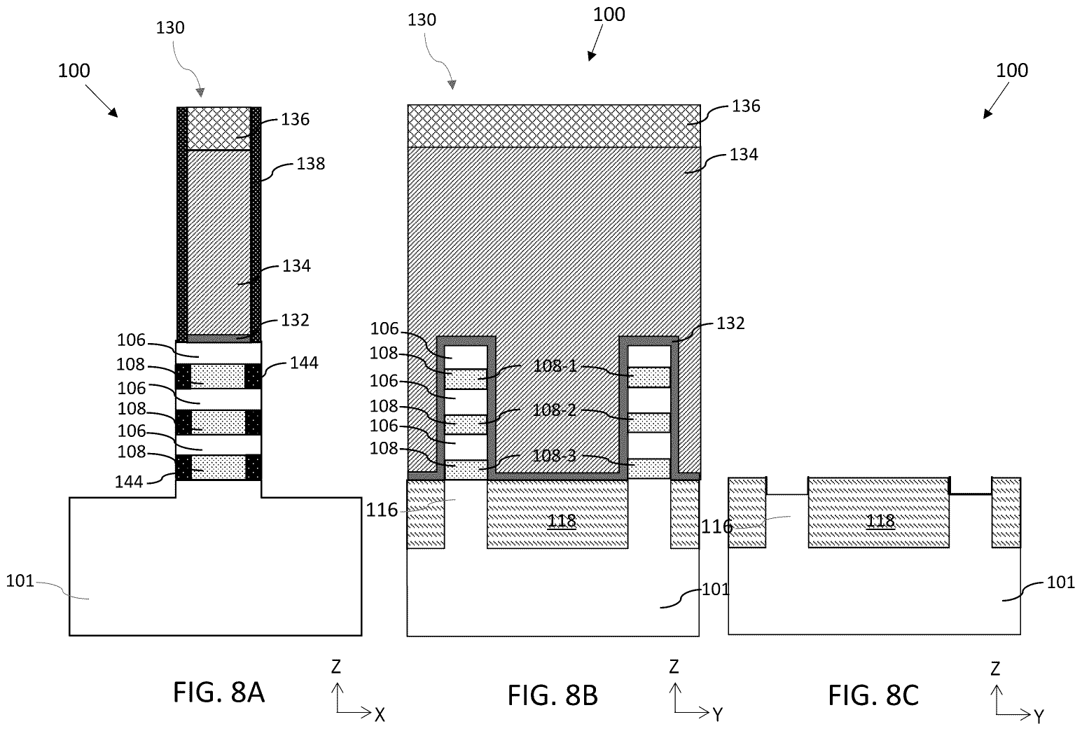

FIGS. 8A, 8B, and 8C are cross-sectional side views of one of various stages of manufacturing the semiconductor device structure 100 taken along line A-A, line B-B, and line C-C of FIG. 6, respectively, in accordance with some embodiments. As shown in FIG. 8A, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

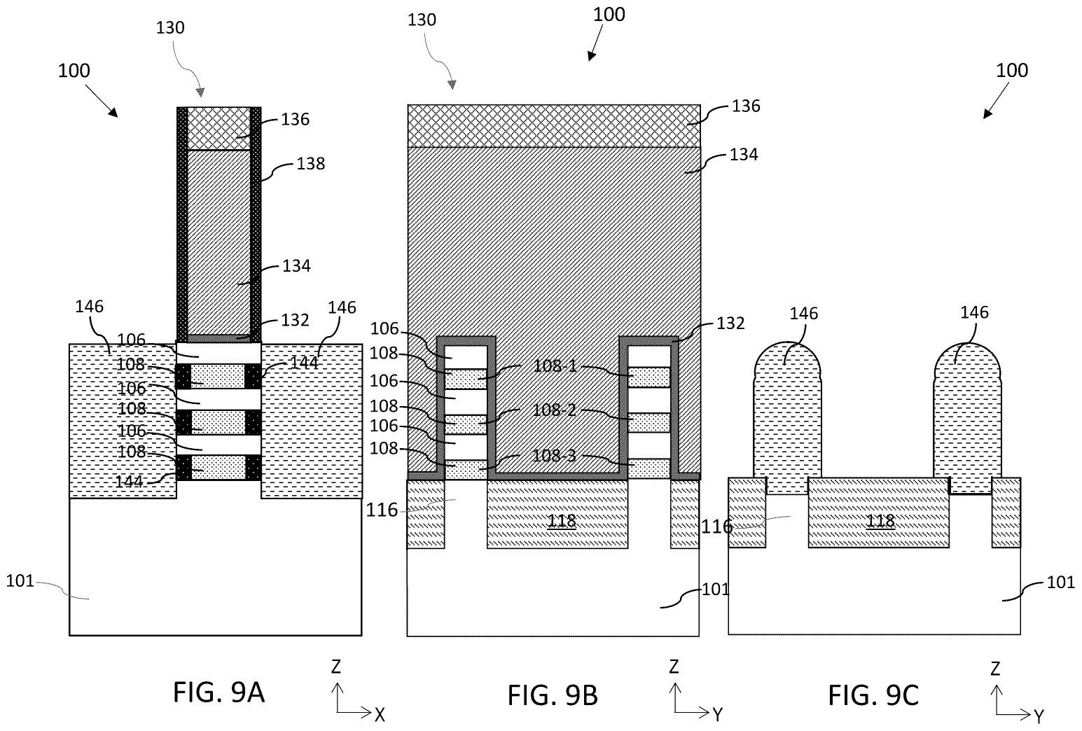

FIGS. 9A, 9B, and 9C are cross-sectional side views of one of various stages of manufacturing the semiconductor device structure 100 taken along line A-A, line B-B, and line C-C of FIG. 6, respectively, in accordance with some embodiments. As shown in FIGS. 9A and 9C, source/drain (S/D) regions 146 are formed from the well portion 116. The S/D regions 146 may grow both vertically and horizontally to form facets, which may correspond to crystalline planes of the material used for the well portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE.

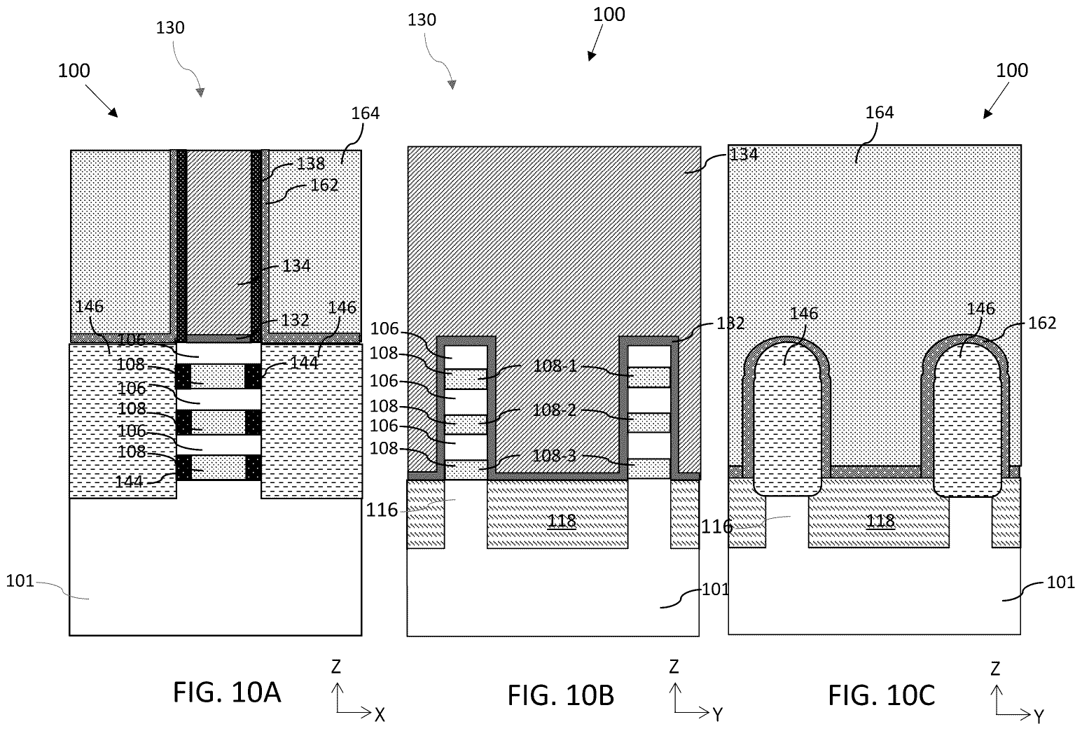

FIGS. 10A, 10B, and 10C are cross-sectional side views of one of various stages of manufacturing the semiconductor device structure 100 taken along line A-A, line B-B, and line C-C of FIG. 6, respectively, in accordance with some embodiments. In FIGS. 10A, 10B, and 10C, a contact etch stop layer (CESL) 162 is conformally formed on the exposed surfaces of the semiconductor device structure 100. The CESL 162 covers the sidewalls of the sacrificial gate structure 130, the insulating material 118, and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIGS. 10A and 10B.

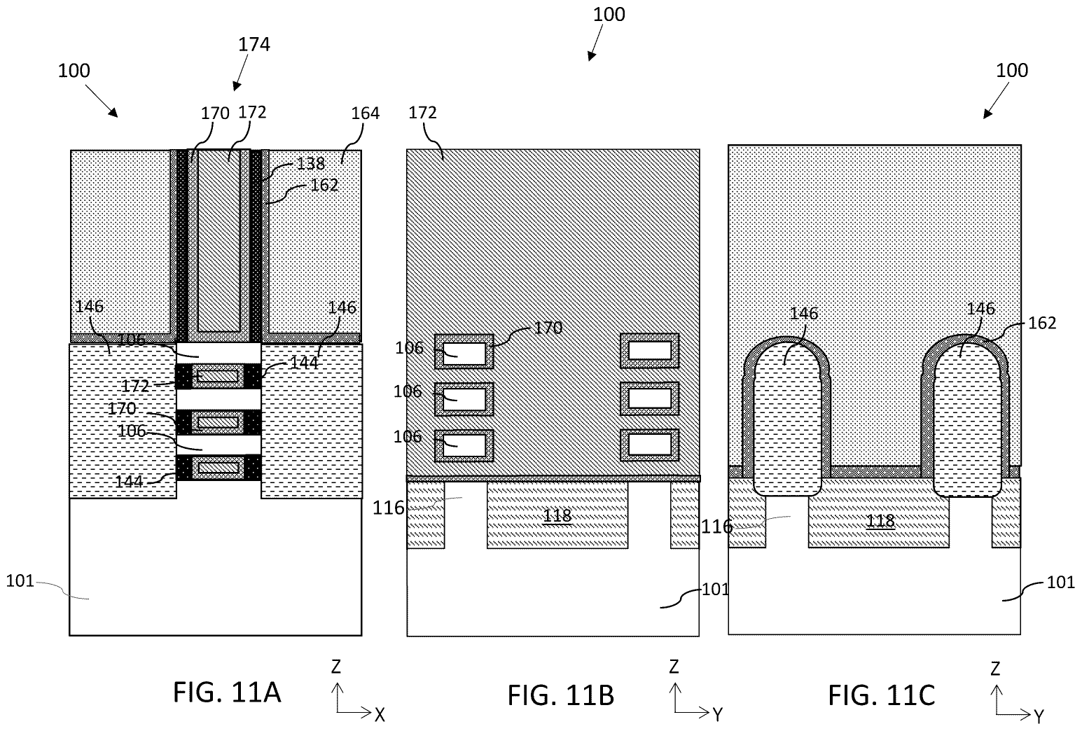

FIGS. 11A, 11B, and 11C are cross-sectional side views of one of various stages of manufacturing the semiconductor device structure 100 taken along line A-A, line B-B, and line C-C of FIG. 6, respectively, in accordance with some embodiments. As shown in FIGS. 11A and 11B, the sacrificial gate structure 130 and the second semiconductor layers 108 are removed. The removal of the sacrificial gate structure 130 and the semiconductor layers 108 forms an opening between gate spacers 138 and between first semiconductor layers 106. The ILD layer 164 protects the S/D regions 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the ILD layer 164, and the CESL 162.

Portions of the second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the gate spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

After the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTIO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 164. The gate dielectric layer 170 and the gate electrode layer 172 formed over the ILD layer 164 are then removed by using, for example, CMP, until the top surface of the ILD layer 164 is exposed.

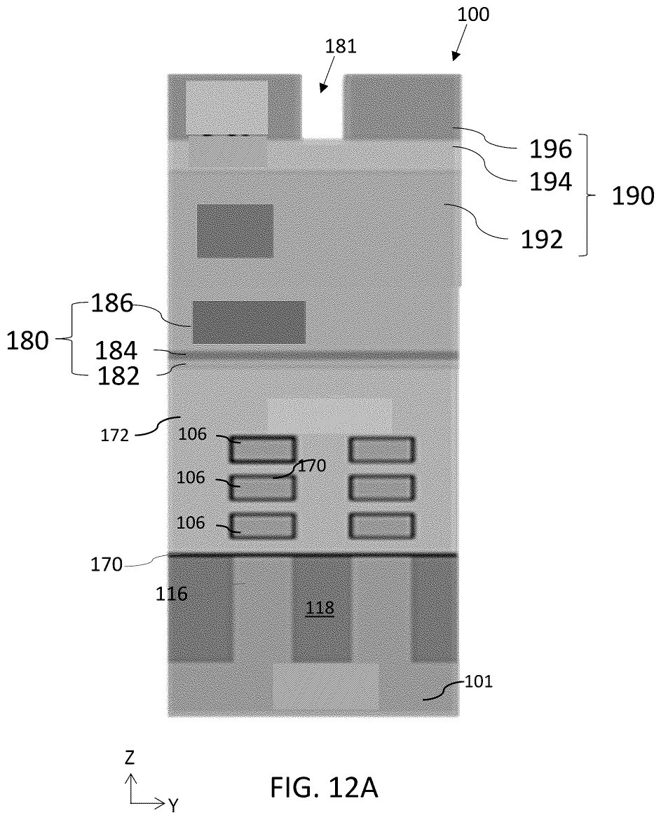

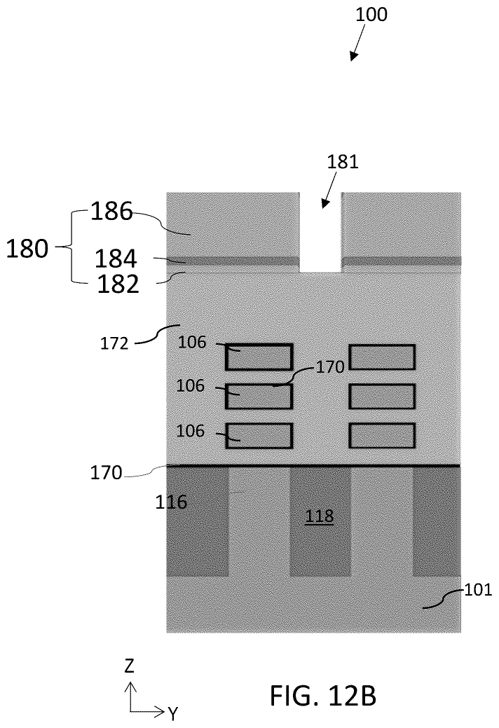

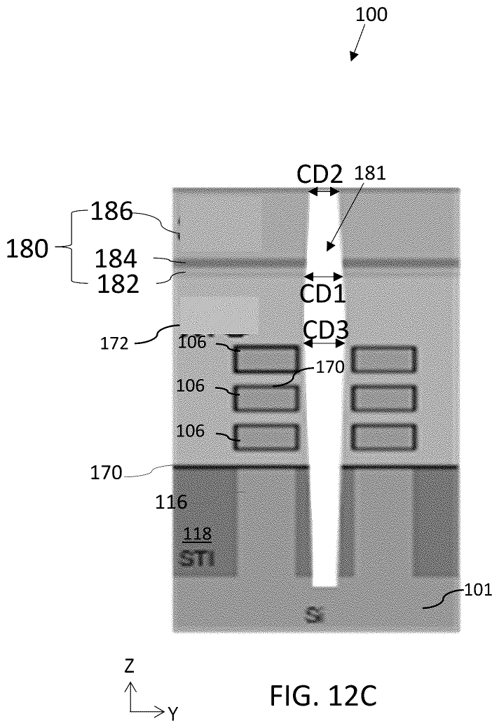

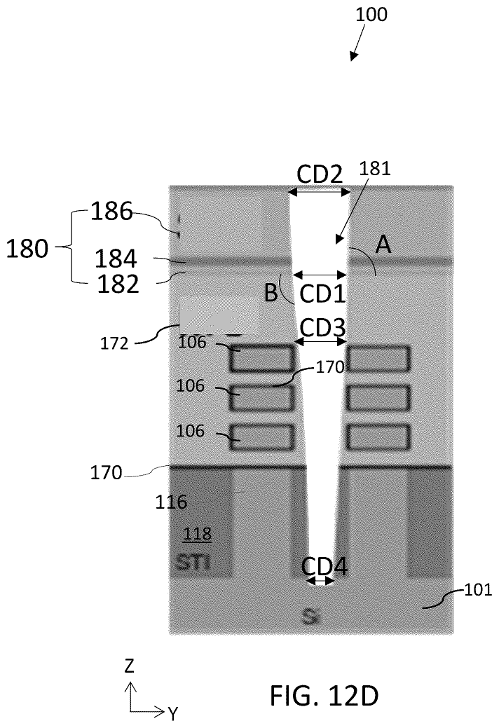

FIGS. 12A-12D are cross-sectional side views of various stages of manufacturing the semiconductor device structure 100 taken along line B-B of FIG. 6, in accordance with some embodiments. As shown in FIG. 12A, a mask structure 180 is formed on the gate electrode layer 172 and the ILD layer 164, and a resist structure 190 is formed on the mask structure 180. In some embodiments, the mask structure 180 includes a first dielectric layer 182, a semiconductor layer 184 deposited on the first dielectric layer, and a second dielectric layer 186 deposited on the semiconductor layer 184. The first and second dielectric layers 182, 186 may include any suitable dielectric material. In some embodiments, the first and second dielectric layers 182, 186 are SiN layers. The semiconductor layer 184 may be any suitable semiconductor layer. In some embodiments, the semiconductor layer 184 is an amorphous silicon layer. In some embodiments, the resist structure 190 is a tri-layer photoresist. For example, the resist structure 190 may include a bottom layer 192 deposited on the mask structure 180, a middle layer 194 deposited on the bottom layer 192, and a photoresist layer 196 deposited on the middle layer 194. The bottom layer 192 and the middle layer 194 are made of different materials such that the optical properties and/or etching properties of the bottom layer 192 and the middle layer 194 are different from each other. In some embodiments, the bottom layer 192 may be a carbon layer, and the middle layer 194 may be a silicon-rich layer designed to provide an etch selectivity between the middle layer 194 and the bottom layer 192. The photoresist layer 196 may be a chemically amplified photoresist layer and can be a positive tone photoresist or a negative tone photoresist. The photoresist layer 196 may include a polymer, such as phenol formaldehyde resin, a poly(norbornene)-co-malaic anhydride (COMA) polymer, a poly(4-hydroxystyrene) (PHS) polymer, a phenol-formaldehyde (bakelite) polymer, a polyethylene (PE) polymer, a polypropylene (PP) polymer, a polycarbonate polymer, a polyester polymer, or an acrylate-based polymer, such as a poly (methyl methacrylate) (PMMA) polymer or poly (methacrylic acid) (PMAA). The photoresist layer 196 may be formed by spin-on coating. The photoresist layer 196 may be patterned to have an opening 181 formed therein.

As shown in FIG. 12B, the opening 181 is extended into the middle layer 194, the bottom layer 192, and the mask structure 180. The opening 181 may be extended into the middle layer 194, the bottom layer 192, and the mask structure 180 by one or more etch processes. In some embodiments, the resist structure 190 is removed during the one or more etch processes to extend the opening 181 into the mask structure 180. In some embodiments, the resist structure 190 is removed after the opening 181 is extended into the mask structure 180. A portion of the gate electrode layer 172 is exposed in opening 181.

As shown in FIG. 12C, the exposed portion of the gate electrode layer 172 is removed. The exposed portion of the gate electrode layer 172 may be removed by any suitable method. In some embodiments, a cyclic process is performed to remove the exposed portion of the gate electrode layer 172. The cyclic process includes a plurality of cycles, and each cycle includes depositing a layer on the exposed portion of the gate electrode layer 172, oxidizing the layer to form an oxide layer, removing portions of the oxide layer, and removing a portion of the exposed portion of the gate electrode layer 172. In some embodiments, the layer may be a silicon-containing layer and may be formed by any suitable process, such as CVD or PECVD. A silicon-containing precursor, such as SiCl₄, may be introduced into the processing chamber in which the semiconductor device structure 100 is disposed therein, and the silicon-containing layer is formed on the exposed surfaces of the semiconductor device structure 100. In some embodiments, the silicon-containing layer is formed on the second dielectric layer 186, the sidewalls of the first dielectric layer 182, the semiconductor layer 184, and the second dielectric layer 186 in the opening 181, and the exposed surface of the gate electrode layer 172. Next, the oxidation process is performed to oxidize the silicon-containing layer to form the oxide layer, such as a silicon oxide layer. The oxidation process may be any suitable oxidation process, such as a thermal oxidation process. Next, a breakthrough etch process is performed to remove portions of the oxide layer formed on horizontal surfaces of the semiconductor device structure 100, such as the portions of the oxide layer formed on the second dielectric layer 186 and the exposed surface of the gate electrode layer 172. The breakthrough etch process may be an anisotropic dry etch process, such as a plasma etch process. In some embodiments, a fluorine-containing etchant, such as C₄F₆, may be used in the anisotropic dry etch process. After the breakthrough etch process, the portion of the gate electrode layer 172 located at the bottom of the opening 181 is exposed, and a main etch process is performed to remove a portion of the gate electrode layer 172. In some embodiments, the main etch process is a dry etch process, such as an anisotropic plasma etch process. One of more etchants may be used in the main etch process. In some embodiments, one or more chlorine-containing etchants, such as BCl₃ and/or Cl₂, may be used. The oxide layer formed on the sidewalls in the opening 181 may be also removed by the one or more chlorine-containing etchants. In some embodiments, a deposition gas, such as a silicon-containing gas, for example SiCl₄, may be introduced into the processing chamber along with the etchants. The deposition gas may form a layer on sidewalls of the gate electrode layer 172 in the opening 181 as the opening 181 extends into the gate electrode layer 172. The layer protects the sidewalls of the gate electrode layer 172 during the main etch process to protect the sidewalls of the gate electrode layer 172. In other words, the oxide layer formed on the sidewalls in the opening 181 may be removed by the etchants of the main etch process, while the deposition gas of the main etch process forms the layer, which may be a silicon layer, on the sidewalls in the opening 181. In some embodiments, the time duration of the main etch process may be substantially short, such as from about 10 seconds to about 20 seconds.

The cycle of depositing a layer on the exposed portion of the gate electrode layer 172, oxidizing the layer to form an oxide layer, removing portions of the oxide layer, and removing a portion of the exposed portion of the gate electrode layer 172 is repeated multiple times so the opening 181 extends through the gate electrode layer 172 and into the insulating material 118, as shown in FIG. 12C. After the opening 181 is first extended into the gate electrode layer 172, the depositing a layer on the exposed portion of the gate electrode layer 172 and oxidizing the layer to form an oxide layer of the cyclic process form the oxide layer on the sidewalls of the gate electrode layer 172 in the opening 181 to protect the sidewalls of the gate electrode layer 172. In some embodiments, the number of cycles ranges from about eight to about 15, such as 12. At the end of the cycles, the opening 181 extends through the gate electrode layer 172. In some embodiments, the opening 181 extends through the gate dielectric layer 170 and the insulating material 118 and into the substrate 101, as shown in FIG. 12C. In some embodiments, the opening 181 is about 5 nm to about 35 nm into the substrate 101.

In some embodiments, one or more wet clean processes may be performed in between the plurality of cycles to remove byproducts formed from the etching processes. For example, in some embodiments, after seven cycles, a wet clean process is performed. The wet clean process does not substantially affect the materials of the semiconductor device structure 100, such as the gate electrode layer 172 and the gate dielectric layer 170. The wet clean process is performed after a first number of cycles are performed, and a second number of cycles are performed after the wet clean process. In some embodiments, the first number of cycles is greater than the second number of cycles. For example, the first number of cycles is includes seven cycles, and the second number of cycles includes five cycles. In some embodiments, each cycle of the first number of cycles includes the main etch process with a first plasma bias voltage, and each cycle of the second number of cycles includes the main etch process with a second plasma bias voltage substantially greater than the first plasma bias voltage. For example, the main etch process of the first number of cycles has a first plasma bias voltage ranging from about 150 V to about 250 V, and the main etch process of the second number of cycles has a second plasma bias voltage ranging from about 800 V to about 1200 V. In some embodiments, the second plasma bias voltage is about three times to about seven times the first plasma bias voltage. The higher plasma bias voltage may lead to a more anisotropic etch process that decreases CD3 but increases CD1 and CD2. With higher bias voltage, CD2 may be increased due to more plasma bombardment. In some embodiments, the critical dimension CD1 is substantially greater than a critical dimension CD2 of the opening 181 at the top of the mask structure 180 and substantially less than a critical dimension CD3 of the opening 181 at a location below the portion of the opening 181 having the critical dimension CD1, as shown in FIG. 12C. In some embodiments, the critical dimension CD3 is at a location adjacent the top surface of the topmost first semiconductor layer 106, as shown in FIG. 12C. Because the main etch process is substantially selective (i.e., the gate electrode layer 172 is etched at a substantially faster rate than the materials of the mask structure 180), the critical dimension CD1 is substantially smaller than the critical dimension CD2. As described above, the second plasma bias voltage is substantially greater than the first plasma bias voltage. As a result, the critical dimension CD3 is substantially greater than the critical dimension CD1.

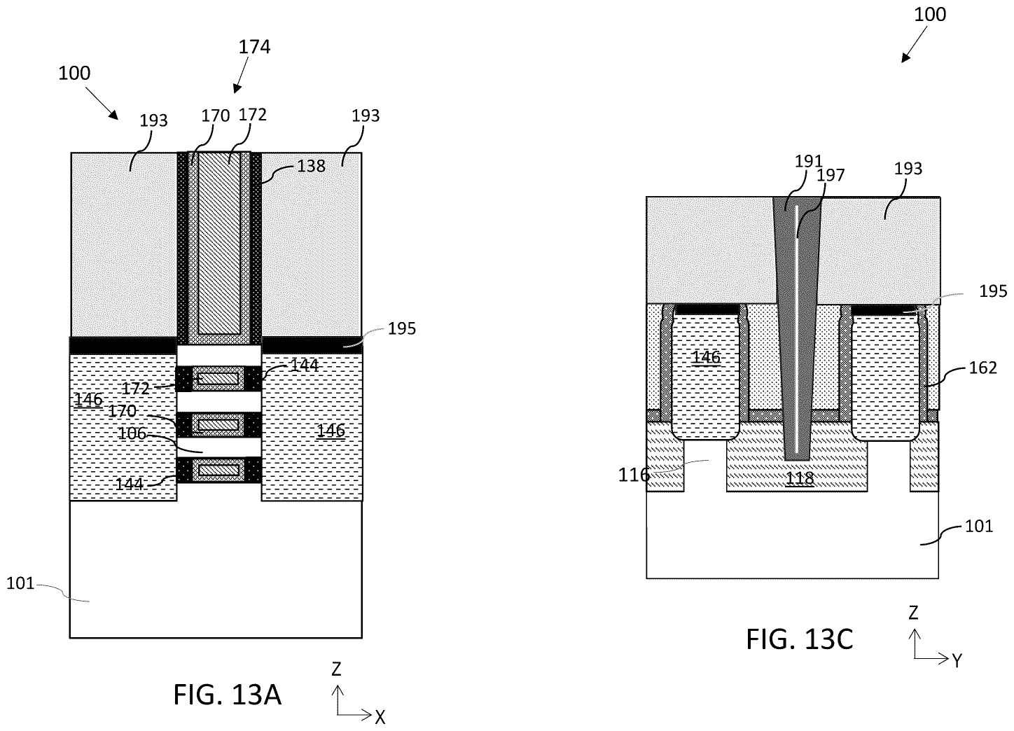

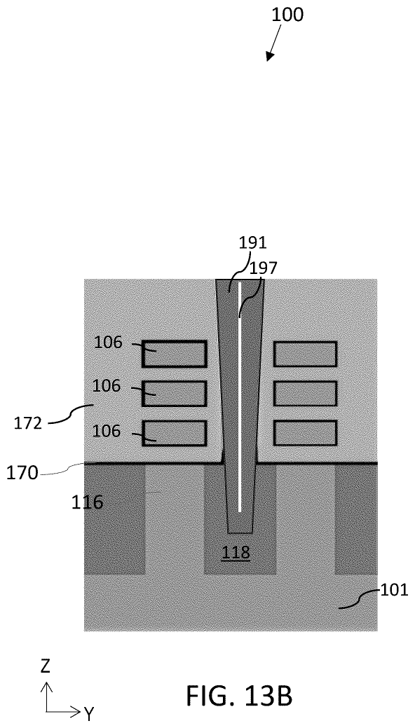

As shown in FIG. 12D, a trim process may be performed to remove portions of the mask structure 180, so the opening 181 in the mask structure 180 is widened. In other words, the trim process enlarges the critical dimension CD2. In some embodiments, a plasma etch process is performed to trim the mask structure 180. The plasma etch process may utilize a fluorine-containing etchant, such as C₄F₆. In some embodiments, the critical dimension CD1 is also enlarged by the trim process. If the critical dimension CD1 gets too large, the conductive contact to be formed on the gate electrode layer 172 may land on a portion of the dielectric material 191 (FIG. 13B) formed in the opening 181, leading to increased contact resistance. In some embodiments, in order to prevent the critical dimension CD1 from getting too large, a carbon-containing gas, such as CH₄, is introduced along with the fluorine-containing etchant during the plasma etch process. The carbon-containing gas may form a polymer layer on the sidewalls of the opening 181. As a result, an angle A formed between the sidewall of the mask structure 180 exposed to the opening 181 and the top surface of the gate electrode layer 172 is greater than about 75 degrees, such as from about 75 degrees to about 90 degrees. If the angle A is greater than about 90 degrees, the critical dimension CD2 may be too small, and a large seam or void may form in the dielectric material 191 (FIG. 13B). On the other hand, if the angle A is less than about 75 degrees, the top portion of the gate electrode layer 172 exposed to the opening 181 may be removed, leading to enlarged critical dimension CD1. In some embodiments, an angle B is formed between the sidewall of the gate electrode layer 172 exposed in the opening 181 and the top surface of the gate electrode layer 172, and the angle B ranges from about 90 degrees to about 95 degrees. In some embodiments, the angle B is substantially greater than the angle A.

In some embodiments, the polymer layer is formed on the sidewalls of the mask structure 180, the gate electrode layer 172, and the insulating material 118 exposed to the opening 181. A plasma process may be performed to remove the polymer layer. In some embodiments, the plasma process is an oxygen plasma burn process, in which the polymer layer is removed by the oxygen-containing plasma. The plasma process is different from the trim process.

After the trim process and the plasma process, a wet clean process may be performed to remove any byproducts from the trim process. In some embodiments, after the wet clean process, the critical dimension CD 1 may range from about 19 nm to about 26 nm, and the critical dimension CD3 may range from about 19 nm to about 26 nm. In some embodiments, the critical dimension CD3 is less than the critical dimension CD1. A critical dimension CD4 located at the bottom of the opening 181 may range from about 12 nm to about 16 nm. In some embodiments, a width of the first semiconductor layer 106 along the Y-direction ranges from about 20 nm to about 40 nm. In some embodiments, the width of the first semiconductor layer 106 may be greater than the critical dimension CD1. In some embodiments, the width of the first semiconductor layer 106 may be smaller than the critical dimension CD1.

FIGS. 13A-13C are various views of one of various stages of manufacturing the semiconductor device structure 100, in accordance with some embodiments. As shown in FIGS. 13A-13C, a dielectric material 191 is formed in the opening 181, the mask structure 180 is removed, and conductive features 193 are formed in the ILD layer 164. Silicide layers 195 may be formed between S/D regions 146 and the conductive features 193. The dielectric material 191 may include any suitable dielectric material, such as SiN, HfO, SiNOₓ, or ZrO. The conductive feature 193 may include any suitable electrically conductive material, such as a metal. The silicide layer 195 may be a metal silicide layer that is a result of a reaction between the metal of the conductive feature 193 and the semiconductor material of the S/D region 146. In some embodiments, a seam 197 is formed in the dielectric material 191. Because the critical dimension CD1 is greater than the critical dimension CD3, the seam 197 may have a dimension along the Y-direction less than about 1 nm.

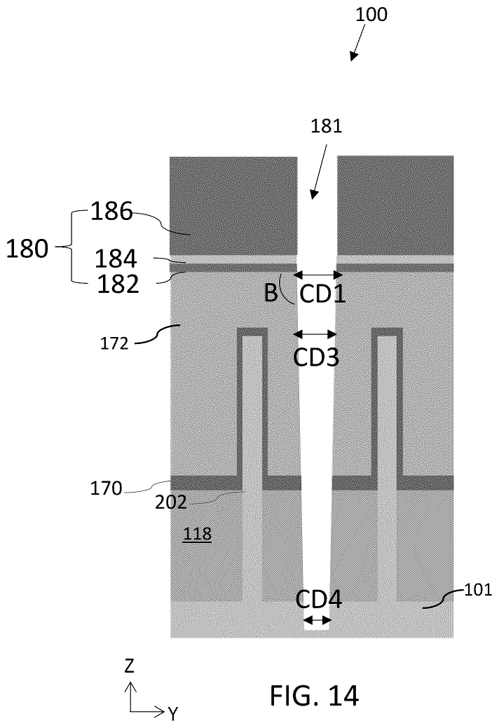

FIG. 14 is a cross-sectional side view of one of various stages of manufacturing the semiconductor device structure 100, in accordance with alternative embodiments. As described above, the semiconductor device structure 100 may include nanostructure channel FETs. In some embodiments, the semiconductor device structure 100 includes FinFETs. As shown in FIG. 14, the semiconductor device structure 100 includes one or more fin structures 202 extending from the substrate 101, the gate dielectric layer 170 formed around the fin structures 202, and the gate electrode layer 172 formed on the gate dielectric layer 170. The opening 181 is formed in the mask structure 180, the gate electrode layer 172, the insulating material 118, and into the substrate 101. In some embodiments, a width of the fin structure 202 along the Y-direction ranges from about 5 nm to about 8 nm, and the critical dimension CD4 is substantially greater than the width of the fin structure 202.

Embodiments of the present disclosure provide a method to form a semiconductor device structure 100. The method includes forming an opening through a gate electrode layer 172 by a cyclic process and performing a trim process to remove portions of a mask structure 180. The cyclic process includes a first plurality of cycles, a second plurality of cycles, and a clean process separating the first and second pluralities of cycles. A main etch process of the first plurality of cycles includes a first plasma bias voltage substantially smaller than a second plasma bias voltage of a main etch process of the second plurality of cycles. Some embodiments may achieve advantages. For example, with the increased plasma bias voltage, the critical dimension CD1 of the portion of the opening 181 located at the top of the gate electrode layer 172 remains to be small. Furthermore, the trim process includes a carbon-containing gas to form a polymer layer on sidewalls of the opening 181, and the critical dimension CD1 is not unnecessarily enlarged.

An embodiment is a method. The method includes forming a fin structure over a substrate, forming an insulating material adjacent the fin structure, depositing a gate dielectric layer over the fin structure and the insulating material, depositing a gate electrode layer on the gate dielectric layer, and forming an opening through the gate electrode layer and the gate dielectric layer into the insulating material by a cyclic process. The cyclic process includes performing a first number of cycles, each cycle of the first number of cycles includes a first main etch process having a first plasma bias voltage, performing a second number of cycles, and each cycle of the second number of cycles includes a second main etch process having a second plasma bias voltage substantially greater than the first plasma bias voltage. The method further includes filling the opening with a dielectric material.

Another embodiment is a method. The method includes forming an insulating material over a substrate, depositing a gate dielectric layer on the insulating material, depositing a gate electrode layer on the gate dielectric layer, forming a mask structure on the gate electrode layer, performing a cyclic process to form an opening through the mask structure and the gate electrode layer, and performing a trim process to remove portions of the mask structure. The trim process includes introducing an etchant and a carbon-containing gas. The method further includes filling the opening with a dielectric material.

A further embodiment is a method. The method includes forming an insulating material over a substrate, depositing a gate dielectric layer on the insulating material, depositing a gate electrode layer on the gate dielectric layer, forming a mask structure on the gate electrode layer, and performing a cyclic process to form an opening through the mask structure and the gate electrode layer. The opening has a first critical dimension at a top of the mask structure, a second critical dimension at a top of the gate electrode layer, a third critical dimension at a location below the second critical dimension, and the second critical dimension is substantially greater than the first critical dimension and substantially less than the third critical dimension. The method further includes performing a trim process to remove portions of the mask structure. The first critical dimension is substantially greater than the second critical dimension, and the second critical dimension is substantially greater than the third critical dimension after the trim process. The method further includes filling the opening with a dielectric material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a fin structure over a substrate;
forming an insulating material adjacent the fin structure;
depositing a gate dielectric layer over the fin structure and the insulating material;
depositing a gate electrode layer on the gate dielectric layer;
forming an opening through the gate electrode layer and the gate dielectric layer into the insulating material by a cyclic process, wherein the cyclic process comprises:
performing a first number of cycles, wherein each cycle of the first number of cycles includes a first main etch process having a first plasma bias voltage; and
performing a second number of cycles, wherein each cycle of the second number of cycles includes a second main etch process having a second plasma bias voltage substantially greater than the first plasma bias voltage; and
filling the opening with a dielectric material.

2. The method of claim 1, wherein the fin structure comprises a plurality of semiconductor layers, and the gate dielectric layer and the gate electrode layer surround a portion of each semiconductor layer of the plurality of semiconductor layers.

3. The method of claim 1, wherein the first plasma bias voltage ranging from about 150 V to about 250 V, and the second plasma bias voltage ranging from about 800 V to about 1200 V.

4. The method of claim 1, wherein the first number of cycles includes more cycles than the second number of cycles.

5. The method of claim 1, wherein each cycle of the first number of cycles comprises:
depositing a layer on the gate electrode layer;
oxidizing the layer to form an oxide layer;
removing a portion of the oxide layer; and
performing the first main etch process to remove a portion of the gate electrode layer.

6. The method of claim 5, wherein the first main etch process uses one or more chlorine-containing etchants.

7. The method of claim 6, wherein the one or more chlorine-containing etchants comprise BCl₃ and Cl₂.

8. The method of claim 1, further comprising performing a clean process between the first number of cycles and the second number of cycles.

9. A method, comprising:
forming an insulating material over a substrate;
depositing a gate dielectric layer on the insulating material;
depositing a gate electrode layer on the gate dielectric layer;
forming a mask structure on the gate electrode layer;
performing a cyclic process to form an opening through the mask structure and the gate electrode layer;
performing a trim process to remove portions of the mask structure, wherein the trim process comprises introducing an etchant and a carbon-containing gas; and
filling the opening with a dielectric material.

10. The method of claim 9, wherein the trim process is a plasma etch process.

11. The method of claim 10, wherein a polymer layer is formed on sidewalls of the opening during the trim process.

12. The method of claim 11, further comprising a plasma process to remove the polymer layer after the trim process.

13. The method of claim 12, wherein the plasma process forms an oxygen-containing plasma.

14. A method, comprising:
forming an insulating material over a substrate;
depositing a gate dielectric layer on the insulating material;
depositing a gate electrode layer on the gate dielectric layer;
forming a mask structure on the gate electrode layer;
performing a cyclic process to form an opening through the mask structure and the gate electrode layer, wherein the opening has a first critical dimension at a top of the mask structure, a second critical dimension at a top of the gate electrode layer, a third critical dimension at a location below the second critical dimension, and the second critical dimension is substantially greater than the first critical dimension and substantially less than the third critical dimension;
performing a trim process to remove portions of the mask structure, wherein the first critical dimension is substantially greater than the second critical dimension, and the second critical dimension is substantially greater than the third critical dimension after the trim process; and filling the opening with a dielectric material.

15. The method of claim 14, wherein a first angle is formed between a sidewall of the mask structure exposed in the opening and a top surface of the gate electrode layer after the trim process, and the first angle ranges from about 75 degrees to about 90 degrees.

16. The method of claim 15, wherein a second angle is formed between a sidewall of the gate electrode layer exposed in the opening and the top surface of the gate electrode layer after the trim process, and the second angle ranges from about 90 degrees to about 95 degrees.

17. The method of claim 16, wherein the second angle is substantially greater than the first angle.

18. The method of claim 14, further comprising forming a plurality of semiconductor layers, wherein the gate dielectric layer and the gate electrode layer surrounds the plurality of semiconductor layers.

19. The method of claim 14, further comprising forming a fin structure, wherein the gate dielectric layer and the gate electrode layer are disposed around the fin structure.

20. The method of claim 14, further comprising performing a plasma process to remove a polymer layer from sidewalls of the openings after the trim process.
